(19) United States
(12) Patent Application Publication
(10) Pub. No.: US 2019/0393118 A1
(43) Pub. Date: Dec. 26, 2019

(54) SEMICONDUCTOR PACKAGE WITH SEALED THERMAL INTERFACE CAVITY WITH LOW THERMAL RESISTANCE LIQUID THERMAL INTERFACE MATERIAL

(71) Applicant: Intel Corporation, Santa Clara, CA (US)

(72) Inventors: Brandon M. RAWLINGS, Chandler, AZ (US); Feras EID, Chandler, AZ (US); Kelly LOFGREEN, Phoenix, AZ (US)

(21) Appl. No.: 16/016,399

(22) Filed: Jun. 22, 2018

(51) Int. Cl. H01L 23/367; H01L 23/42; H01L 23/00; H01L 21/52; H01L 25/065

(52) U.S. Cl. CPC H01L 23/367; H01L 23/42; H01L 24/29; H01L 2224/8385; H01L 24/83; H01L 25/0655; H01L 2224/29191; H01L 21/52

(57) ABSTRACT

A package is disclosed. The package includes a substrate, a die on the substrate, an integrated heat spreader on the substrate that encloses the die, the integrated heat spreader including a hole that extends through the integrated heat spreader, an air permeable adhesive contacting the integrated heat spreader and forming a cavity underneath the integrated heat spreader, and a liquid metal thermal interface material filling the cavity. A sealant plugs the hole that extends through the integrated heat spreader.

### TECHNICAL FIELD

Embodiments of the disclosure pertain to semiconductor packages that use thermal interface materials and, in particular, to a semiconductor package with a sealed thermal interface cavity with low thermal resistance liquid thermal interface material.

### BACKGROUND

Thermal interface materials are used in packages to minimize thermal resistance between the die and the integrated heat spreader. Some conventional packages use polymer thermal interface material which suffers from low thermal conductivity and degradation after reliability testing. Solder thermal interface material offers better performance but requires die backside metallization which adds cost and complexity to the die fabrication process. In addition, solder thermal interface material is not compatible with ball-grid-array (BGA) products.

The low thermal conductivity of polymer thermal interface material becomes a significant drawback when a thick layer of thermal interface material is needed, e.g., to counter integrated heat spreader tilt or to make up for different die heights in a multichip package (MCP). The thermal degradation of polymer thermal interface material after reliability testing can be especially apparent near die edges after thermal cycling. Solder thermal interface material offers better performance but at the expense of requiring die back side metallization, which adds cost and complexity to the wafer fabrication process. Moreover, current solder thermal interface material is not compatible with BGA products. Conventional approaches do not provide a high volume manufacturing compatible process for using liquid metal thermal interface materials.

### BRIEF DESCRIPTION OF THE DRAWINGS

FIG. 1A is an illustration of a semiconductor package with an integrated heat spreader according to an embodiment.

FIG. 1B is an illustration of a semiconductor package with an integrated heat spreader according to an embodiment.

FIG. 1C is an illustration of a semiconductor package with an integrated heat spreader according to an embodiment.

FIG. 1D is an illustration of a semiconductor package with an integrated heat spreader according to an embodiment.

FIG. 2 is an illustration of a multichip semiconductor package with an integrated heat spreader according to an embodiment.

FIG. 3A-FIG. 3F are illustrations of cross-sections of a semiconductor package with an integrated heat spreader during manufacture according to an embodiment.

FIG. 4 is a schematic of a computer system according to an embodiment.

### DESCRIPTION OF THE EMBODIMENTS

A semiconductor package with a sealed thermal interface cavity with low thermal resistance liquid thermal interface material is described. In the following description, numerous specific details are set forth, such as specific integration and material regimes, in order to provide a thorough understanding of embodiments of the present disclosure. It will be apparent to one skilled in the art that embodiments of the present disclosure may be practiced without these specific details. In other instances, well-known features, such as integrated circuit design layouts, are not described in detail in order to not unnecessarily obscure embodiments of the present disclosure. Furthermore, it is to be appreciated that the various embodiments shown in the Figures are illustrative representations and are not necessarily drawn to scale.

Certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

Liquid metal thermal interface material has been shown experimentally to match and even exceed the thermal performance of solder thermal interface material both before and after reliability testing. In addition, liquid metal thermal interface material is very compliant. Compliance is an important characteristics for preventing large die stresses due to die/substrate warpage (especially during thermal cycling). Because liquid metal thermal interface material can be strongly reactive with metals such as aluminum, it is important to constrain it to the die-integrated heat spreader interface and eliminate the possibility of it leaking outside the package and reacting with other equipment (e.g., during assembly or at the OEM). Consequently, applying liquid metal thermal interface material in a high-volume manufacturing compatible manner and ensuring it is constrained to the desired locations (e.g., only between die and integrated heat spreader) presents significant challenges. Moreover, there is no process known or used today to enable the application of liquid metal thermal interface material to processor packages in high volume production.

Other thermal interface materials such as polymers suffer from low thermal conductivity and degradation after testing. In addition, thermal interface materials such as those based on solder are not compatible with ball grid array (BGA) technology. An approach that addresses and overcomes the shortcomings of previous approaches is disclosed herein. As part of the approach, an architecture and methodology for creating a sealed thermal interface cavity, that is filled with low thermal resistance, liquid metal thermal interface material, is disclosed. In an embodiment, the top and the bottom perimeter of the cavity are defined by parts of the top surface of the substrate and the upper inside surface of the integrated heat spreader. In other embodiments, the top and the bottom perimeter of the cavity are defined by the top surface of the semiconductor die and the upper inside surface of the integrated heat spreader. In an embodiment, a polymer is used to seal the integrated heat spreader and the substrate. In other embodiments, a polymer is used to define the lateral walls of the cavity and to seal the perimeter of the cavity. In an embodiment, the cavity is completely filled with liquid metal thermal interface material by means of a weak-vacuum-assisted, high-volume-manufacturing compatible process. The liquid metal thermal interface material is constrained to the cavity with no risk of the material leaking or reacting with external parts or equipment. The liquid metal is liquid at operating temperatures, characterized by low thermal resistance, and is non-toxic.

The disclosed approach provides a high volume manufacturing (HVM) compatible process and a package architecture in which a low thermal resistance, compliant thermal interface material is deployed that has a performance that is on-par with solder thermal interface material (STIM) but without requiring backside metallization (BSM) or having the other STIM associated challenges such as multichip package (MCP) and BGA incompatibility.

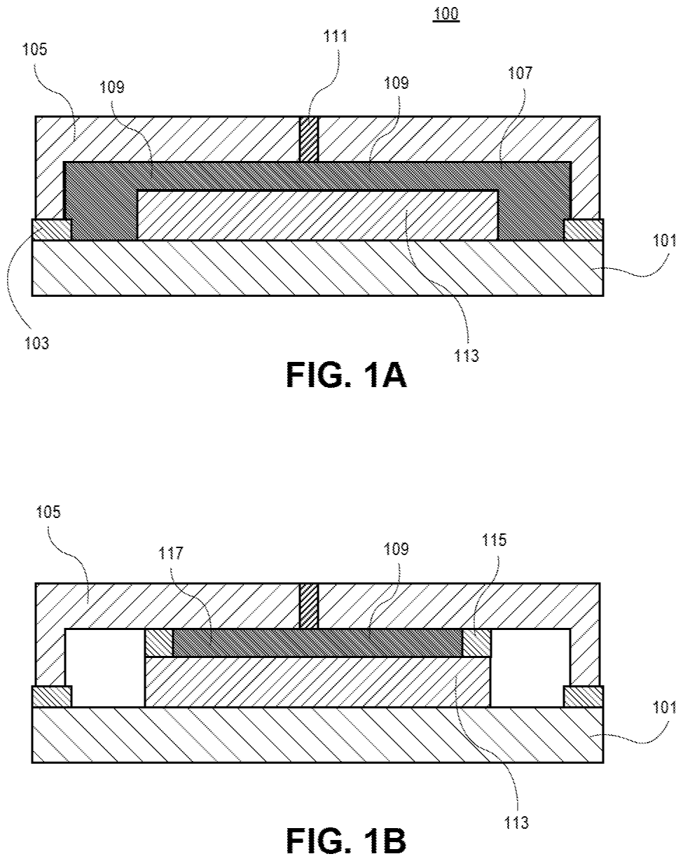

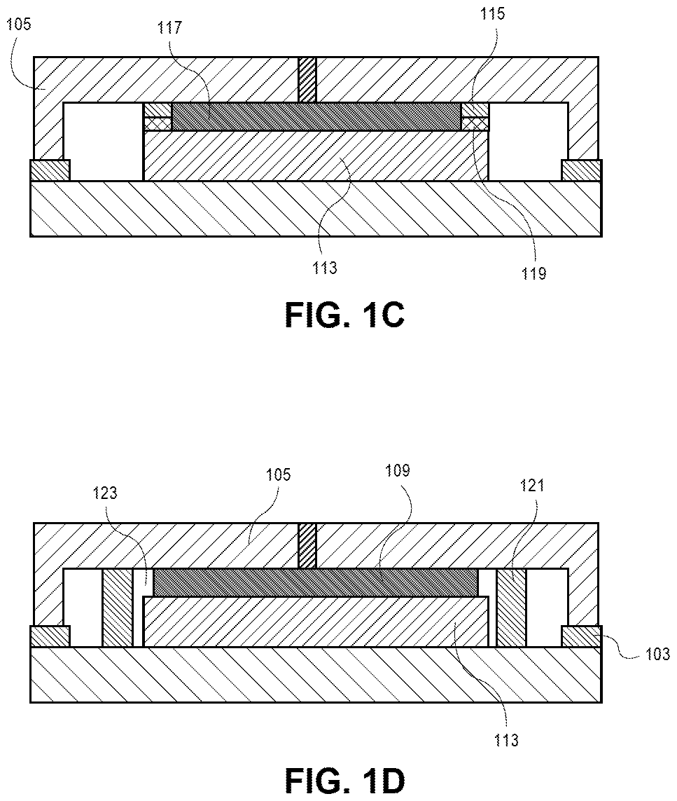

FIG. 1A is an illustration of a semiconductor package 100 with an integrated heat spreader according to an embodiment. FIG. 1A includes substrate 101, air permeable adhesive 103, integrated heat spreader 105, cavity 107, liquid metal thermal interface material 109, hole 111 and die 113.

Referring to FIG. 1A, the integrated heat spreader 105 is attached to the top of the substrate 101. The integrated heat spreader 105 is attached to the substrate 101 by air permeable adhesive 103. The die 113 is attached to the top surface of the substrate 101. The cavity 107 is formed by the space between the substrate 101 and the integrated heat spreader 105 that is not occupied by the die 113. The hole 111 is formed in the top surface of the integrated heat spreader 105. The liquid metal thermal interface material 109 is formed in the cavity 107.

In an embodiment, the substrate 101 can be formed from organic, ceramic, or glass materials and may contain metallic traces or vias. In other embodiments, the substrate 101 can be formed from other types of materials. In an embodiment, the air permeable adhesive 103 can be formed from polydimethylsiloxane (PDMS) or other silicones. In other embodiments, the air permeable adhesive 103 can be formed from other materials. In an embodiment, the integrated heat spreader 105 can be formed from materials such as copper, aluminum, nickel-plated copper or nickel-plated aluminum. In other embodiments, the integrated heat spreader 105 can be formed from other materials. In an embodiment, the liquid metal thermal interface material 109 can be formed from materials such as gallium, or an alloy of gallium with indium and/or tin. In other embodiments, the liquid metal thermal interface material 109 can be formed from other materials.

Referring again to FIG. 1A, during the package fabrication process the interfacial volume between the die 113 and the integrated heat spreader 105 is filled with the liquid metal thermal interface material 109. The liquid metal thermal interface material 109 is constrained to the cavity 107. The cavity 107 has lateral walls which are partially formed by the air permeable adhesive 103. In an embodiment, the hole 111 in the integrated heat spreader 105 is used to enable vacuum-assisted filling of the cavity 107 with the liquid metal thermal interface material 109. After the cavity 107 is filled, the hole 111 in the integrated heat spreader 105 may be sealed.

FIG. 1B is an illustration of a semiconductor package 100 with an integrated heat spreader according to an embodiment. FIG. 1B includes in addition to the structures described with reference to FIG. 1A, additional air permeable adhesive 115 and space 117.

Referring to FIG. 1B, air permeable adhesive 115 is formed above the die 113 and below the integrated heat spreader 105. The air permeable adhesive 115 attaches the integrated heat spreader 105 to the die 113 and creates the space 117. In an embodiment, the air permeable adhesive 115 can be formed from PDMS. In other embodiments, the air permeable adhesive 115 can be formed from other materials. In the FIG. 1B embodiment, the air permeable adhesive 115 can be used to confine the liquid metal thermal interface material 109 to the space 117.

As shown in FIG. 1B, the adhesive 115 can be used along the periphery of the semiconductor die 113 and not just on the substrate 101 as shown in FIG. 1A. This arrangement constrains the liquid metal thermal interface material 109 to the die-IHS interface (instead of also flowing over the substrate as shown in FIG. 1A). It minimizes the volume of liquid metal thermal interface material 109 required and also eliminates the risk of a reaction of any exposed substrate traces or metallization with the liquid metal thermal interface material 109.

FIG. 1C is an illustration of a semiconductor package 100 with an integrated heat spreader 105 according to an embodiment. FIG. 1C includes in addition to the structures described with reference to FIG. 1B, solid frame 119.

Referring to FIG. 1C, in an embodiment, the solid frame 119 is formed below the air permeable adhesive 115. In other embodiments, the solid frame 119 can be formed above the air permeable adhesive 115. In an embodiment, the solid frame 119 can be formed from material that has a higher thermal conductivity compared to adhesive 115. For example, in an embodiment, the solid frame 119 can be formed from a metal such as copper, aluminum or a metal-ceramic composite such as Cu and AL2O3. In other embodiments, the solid frame 119 can be formed from other materials. In an embodiment, the solid frame 119 is used to set the gap height. In an embodiment, the gap height is the height of the space 117 between the integrated heat spreader 105 and the die 113.

As shown in FIG. 1C, to set the gap height, and/or to minimize the thermal impact of the adhesive on the die periphery, solid frame 119 is formed from a higher conductivity solid material. In an embodiment, an option for depositing the solid frame 119 material is a high throughput additive manufacturing method like cold spray.

FIG. 1D is an illustration of a semiconductor package 100 with an integrated heat spreader 105 according to an embodiment. FIG. 1D includes in addition to the structures described with reference to FIG. 1A-FIG. 1C, air permeable adhesive 121 and space 123.

Referring to FIG. 1D, the air permeable adhesive 121 is formed between the top inner surface of the integrated heat spreader 105 and the top surface of the substrate 101. The air permeable adhesive 121 attaches the integrated heat spreader 105 to the die 113 and creates the space 123. In an embodiment, the air permeable adhesive 121 can be formed from PDMS. In other embodiments, the air permeable adhesive 121 can be formed from other materials. In the FIG. 1D embodiment, the air permeable adhesive 121 can be used to confine the liquid metal thermal interface material 109 to the space 123. In an embodiment, the air permeable adhesive 121 forms an inner seal underneath the integrated heat spreader 105 that is outside of the die shadow area but nearer to the die 113 than the air permeable adhesive 103. This inner seal defines the space 123.

Although FIG. 1D shows semiconductor package 100 with an integrated heat spreader 105 for a single die the configuration can also be applied to multichip configurations. The architecture shown in FIG. 1D strikes a balance between minimizing the amount of thermal interface material that is used and ensuring that none of the die area is covered by low conductivity sealant.

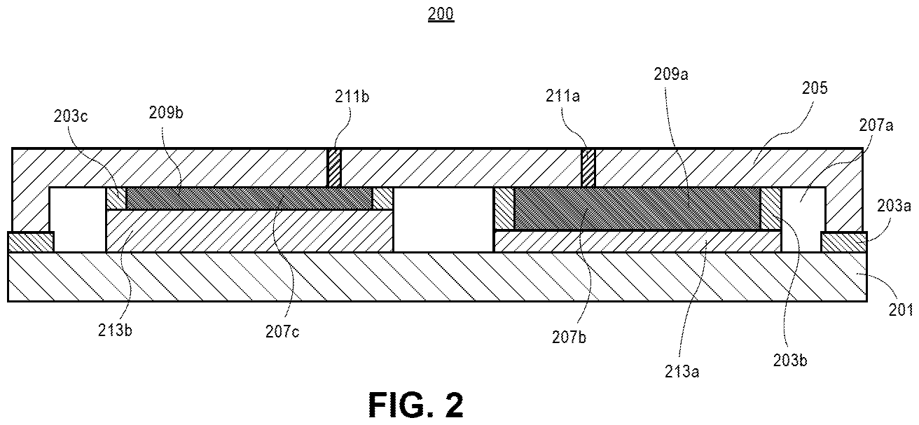

FIG. 2 is an illustration of a multichip semiconductor package 200 with an integrated heat spreader according to an embodiment. FIG. 2 includes substrate 201, air permeable adhesive 203a, air permeable adhesive 203b, air permeable adhesive 203c, integrated heat spreader 205, package cavity 207a, first die cavity 207b, second die cavity 207c, thermal interface material 209a, thermal interface material 209b, hole 211a, hole 211b, die 213a and die 213b.

Referring to FIG. 2, the integrated heat spreader 205 is attached to the top of the substrate 201. The integrated heat spreader 205 is attached to the substrate 201 by air permeable adhesive 203a. The first die 213a is attached to the top surface of the substrate 201. The second die 213b is attached to the top surface of the substrate 201. The cavity 207a is formed by the space between the substrate 201 and the integrated heat spreader 205. The cavity 207b is formed by the space between the top surface of the first die 213a and the integrated heat spreader 205. The cavity 207c is formed by the space between the top surface of the second die 213b and the integrated heat spreader 205. The hole 211a is formed in the top surface of the integrated heat spreader 205 that is located above the first die 213a. The hole 211b is formed in the top surface of the integrated heat spreader 205 that is located above the second die 213b. The thermal interface material 209a is formed in the cavity 207b. The thermal interface material 209b is formed in the cavity 207c.

In an embodiment, the substrate 201 can be formed from organic, ceramic, or glass materials and may contain metallic traces or vias. In other embodiments, the substrate 201 can be formed from other types of materials. In an embodiment, the air permeable adhesive 203a, 203b and 203c can be formed from PDMS or other silicones. In other embodiments, the air permeable adhesive 203a, 203b and 203c can be formed from other materials. In an embodiment, the integrated heat spreader 205 can be formed from materials such as copper, aluminum, nickel plated copper or nickel plated aluminum. In an embodiment, the integrated heat spreader 205 can be formed from other materials. In an embodiment, the thermal interface material 209a and 209b can be formed from materials such as gallium, an alloy of gallium with indium and/or tin, eutectic gallium indium, or gallinstan. In other embodiments, the thermal interface material 209a and 209b can be formed from other materials.

Referring to FIG. 2, an advantage of one or more embodiments is that it can be employed despite height variations between the semiconductor die 213a and the semiconductor die 213b, since the thermal interface materials 209a and 209b are applied after the integrated heat spreader 205 is assembled. By using enough liquid metal thermal interface material volume, any cavity between the integrated heat spreader 205 and the different semiconductor die 213a and 213b can be filled regardless of gap height. The high conductivity of the liquid metal interface material makes it a suitable approach for multichip packages where different thermal interface material thicknesses can be used for dies of different heights.

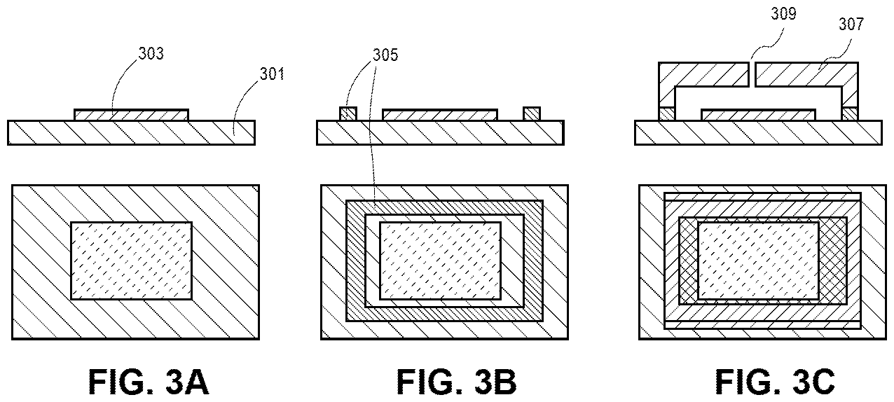

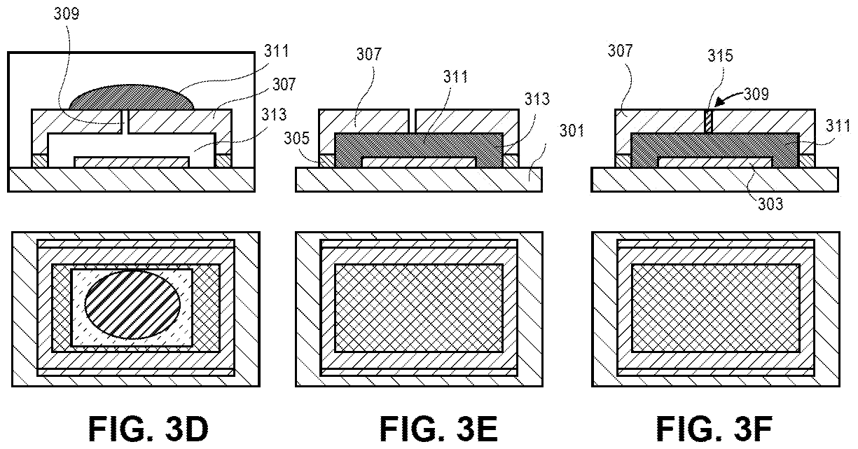

FIG. 3A-FIG. 3F are illustrations of cross-sections of a semiconductor package 300 that includes an integrated heat spreader during manufacture according to an embodiment. FIG. 3A-FIG. 3F illustrate a process flow for fabricating a semiconductor package 300 that includes an integrated heat spreader according to an embodiment.

Referring to FIG. 3A, after one or more operations, a semiconductor die 303 is attached to the top surface of a substrate 301. In an embodiment, the substrate 301 can be formed from organic, ceramic, or glass materials and may contain metallic traces or vias. In other embodiments, the substrate 301 can be formed from other types of materials.

Referring to FIG. 3B, after one or more operations that result in the cross-section shown in FIG. 3A, air permeable adhesive 305 is formed on the top surface of the substrate 301. In an embodiment, the air permeable adhesive 305 operates as a barrier and is applied around the perimeter of the semiconductor die or onto the substrate along the perimeter of the integrated heat spreader to be assembled at a later operation. In an embodiment, the adhesive can be formed from PDMS, which is capable of bonding to silicon, metals, and dielectrics with surface preparation. In an embodiment, PDMS can be dispensed or prefabricated and assembled, then thermally cured in situ. The order of assembly between the polymer barrier and the die, substrate, or integrated heat spreader can vary, and any suitable order can be used.

Referring to FIG. 3C, after one or more operations that result in the cross-section shown in FIG. 3B, the integrated heat spreader 307 is attached to the substrate 301. In an embodiment, the integrated heat spreader 307 has a small hole 309 to allow vacuum assisted liquid metal thermal interface material filling of the cavity.

Referring to FIG. 3D, after one or more operations that result in the cross-section shown in FIG. 3C, liquid metal thermal interface material 311 is formed on the top surface of the integrated heat spreader 307 over the hole 309 in the integrated heat spreader 307. In an embodiment, a small volume of the liquid metal thermal interface material 311 is dispensed over the hole 309 in the integrated heat spreader 307. In an embodiment, the liquid metal thermal interface material 311 can be gallium, or an alloy of gallium with indium, tin, or other metals (e.g., eutectic gallium indium, galinstan, etc). Such alloys have liquidus temperatures that are close to or below room temperature (e.g., below 30° C., with some as low as −19° C.). At the stage shown in FIG. 3D, the cavity 313 formed between the die 303 and integrated heat spreader 307 is still filled with air.

Referring to FIG. 3E, after one or more operations that result in the cross-section shown in FIG. 3D, the liquid metal thermal interface material 311 is drawn into the cavity 313 that is formed by the integrated heat spreader 307 and the substrate 301. In an embodiment, the assembly (or tray of assemblies) is placed in a vacuum chamber. The vacuum allows most of the air in the cavity to be evacuated through the air-permeable adhesive barrier 305. Upon restoring the assembly to atmospheric conditions, a positive pressure is created on the liquid metal thermal interface material 311, causing it to flow inside and fill the cavity. In an embodiment, the process uses a weak vacuum to cause the flow of the liquid metal thermal interface material 311. This process is aided by the permeability of air through the polymer barrier during vacuum application.

Referring to FIG. 3F, after one or more operations that result in the cross-section shown in FIG. 3E, a sealant 315 is formed in the hole 309 in the integrated heat spreader 307 in order to seal the liquid metal thermal interface material 311 in the cavity 313. More specifically, the hole 309 in the integrated heat spreader 307 is plugged with the sealant 315. The cavity 313 is sealed and the liquid metal thermal interface material 311 is constrained to the desired location. The hole 309 is shown in the middle of the integrated heat spreader 307 in FIG. 3F, but it can be located anywhere within the shadow area of the die 303. In an embodiment, an option for minimizing the impact of the thermal resistance of the sealant 315 that is formed in the hole 309 can include but is not limited to using a high conductivity material as the sealant (e.g., metal filled epoxy) or forming the hole 309 in an integrated heat spreader 307 region corresponding to a cool (no hotspot) semiconductor die location. In an embodiment, because the hole 309 is very small, e.g., 50 um-250 um in diameter in an embodiment, any added thermal resistance will be negligible. In other embodiments, the hole can have other diameters.

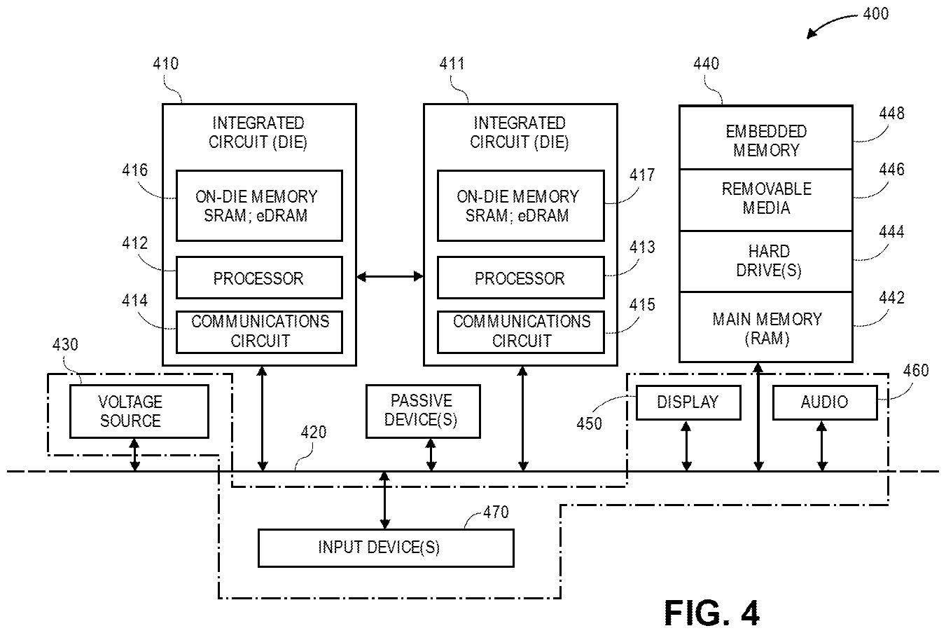

FIG. 4 is a schematic of a computer system 400, in accordance with an embodiment of the present invention. The computer system 400 (also referred to as the electronic system 400) as depicted can embody semiconductor package 100 or semiconductor package 200, according to any of the several disclosed embodiments and their equivalents as set forth in this disclosure. The computer system 400 may be a mobile device such as a netbook computer. The computer system 400 may be a mobile device such as a wireless smart phone. The computer system 400 may be a desktop computer. The computer system 400 may be a hand-held reader. The computer system 400 may be a server system. The computer system 400 may be a supercomputer or high-performance computing system.

In an embodiment, the electronic system 400 is a computer system that includes a system bus 420 to electrically couple the various components of the electronic system 400. The system bus 420 is a single bus or any combination of busses according to various embodiments. The electronic system 400 includes a voltage source 430 that provides power to the integrated circuit 410. In some embodiments, the voltage source 430 supplies current to the integrated circuit 410 through the system bus 420.

The integrated circuit 410 is electrically coupled to the system bus 420 and includes any circuit, or combination of circuits according to an embodiment. In an embodiment, the integrated circuit 410 includes a processor 412 that can be of any type. As used herein, the processor 412 may mean any type of circuit such as, but not limited to, a microprocessor, a microcontroller, a graphics processor, a digital signal processor, or another processor. In an embodiment, the processor 412 includes, or is coupled with, semiconductor package 100 or semiconductor package 200, as disclosed herein. In an embodiment, SRAM embodiments are found in memory caches of the processor. Other types of circuits that can be included in the integrated circuit 410 are a custom circuit or an application-specific integrated circuit (ASIC), such as a communications circuit 414 for use in wireless devices such as cellular telephones, smart phones, pagers, portable computers, two-way radios, and similar electronic systems, or a communications circuit for servers. In an embodiment, the integrated circuit 410 includes on-die memory 416 such as static random-access memory (SRAM). In an embodiment, the integrated circuit 410 includes embedded on-die memory 416 such as embedded dynamic random-access memory (eDRAM).

In an embodiment, the integrated circuit 410 is complemented with a subsequent integrated circuit 411. Useful embodiments include a dual processor 413 and a dual communications circuit 415 and dual on-die memory 417 such as SRAM. In an embodiment, the dual integrated circuit 410 includes embedded on-die memory 417 such as eDRAM.

In an embodiment, the electronic system 400 also includes an external memory 440 that in turn may include one or more memory elements suitable to the particular application, such as a main memory 442 in the form of RAM, one or more hard drives 444, and/or one or more drives that handle removable media 446, such as diskettes, compact disks (CDs), digital variable disks (DVDs), flash memory drives, and other removable media known in the art. The external memory 440 may also be embedded memory 448 such as the first die in a die stack, according to an embodiment.

In an embodiment, the electronic system 400 also includes a display device 450, an audio output 460. In an embodiment, the electronic system 400 includes an input device such as a controller 470 that may be a keyboard, mouse, trackball, game controller, microphone, voice-recognition device, or any other input device that inputs information into the electronic system 400. In an embodiment, an input device 470 is a camera. In an embodiment, an input device 470 is a digital sound recorder. In an embodiment, an input device 470 is a camera and a digital sound recorder.

As shown herein, the integrated circuit 410 can be implemented in a number of different embodiments, including a package substrate including semiconductor package 100 or semiconductor package 200, according to any of the several disclosed embodiments and their equivalents, an electronic system, a computer system, one or more methods of fabricating an integrated circuit, and one or more methods of fabricating an electronic assembly that includes a package substrate including semiconductor package 100 or semiconductor package 200, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates including semiconductor package 100 or semiconductor package 200 embodiments and their equivalents. A foundation substrate may be included, as represented by the dashed line of FIG. 4. Passive devices may also be included, as is also depicted in FIG. 4. Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of the present disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of the present application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

The following examples pertain to further embodiments. The various features of the different embodiments may be variously combined with some features included and others excluded to suit a variety of different applications.

### Example Embodiment 1

A package includes a substrate, a die on the substrate, an integrated heat spreader on the substrate that encloses the die, the integrated heat spreader including a hole that extends through the integrated heat spreader, an air permeable adhesive contacting the integrated heat spreader and forming a cavity underneath the integrated heat spreader, and a liquid metal thermal interface material filling the cavity. A sealant plugs the hole that extends through the integrated heat spreader.

### Example Embodiment 2

The package of example embodiment 1, wherein the air permeable adhesive is formed on a perimeter of the substrate.

### Example Embodiment 3

The package of example embodiment 1, wherein the air permeable adhesive is formed on a perimeter of the die.

### Example Embodiment 4

The package of example embodiment 1, wherein the air permeable adhesive is formed outside of a perimeter of the die and inside of a perimeter of the integrated heat spreader.

### Example Embodiment 5

The package of example embodiment 3, wherein a material having greater conductivity than the air permeable adhesive is formed above the air permeable adhesive.

### Example Embodiment 6

The package of example embodiment 5, wherein the material having greater conductivity than the air permeable adhesive determines a gap height between the integrated heat spreader and the die.

### Example Embodiment 7

The package of example embodiment 6, wherein the hole is offset from the center of the die.

### Example Embodiment 8

A package includes a substrate, a first die on the substrate, a second die on the substrate, an integrated heat spreader on the substrate and enclosing the first die and the second die, the integrated heat spreader including a first hole and a second hole that extend through the integrated heat spreader, a first air permeable adhesive contacting the integrated heat spreader and forming a first cavity underneath the integrated heat spreader and above the first die, the second air permeable adhesive contacting the integrated heat spreader and forming a second cavity underneath the integrated heat spreader and above the second die, a first liquid metal thermal interface material filling the first cavity, a second liquid metal thermal interface material filling the second cavity, and a first sealant plugging the first hole that extends through the integrated heat spreader. A second sealant plugs the second hole that extends through the integrated heat spreader.

### Example Embodiment 9

The package of example embodiment 8, wherein the first die and the second die have different heights.

### Example Embodiment 10

The package of example embodiment 8, wherein a third air permeable adhesive is formed on a perimeter of the substrate.

### Example Embodiment 11

The package of example embodiment 8, wherein the first air permeable adhesive is formed on a perimeter of the first die.

### Example Embodiment 12

The package of example embodiment 8, wherein the second air permeable adhesive is formed on a perimeter of the second die.

### Example Embodiment 13

The package of example embodiment 8, wherein the first hole is formed above the first cavity.

### Example Embodiment 14

The package of example embodiments 8, 9, 10, 11, 12 or 13 wherein the second hole is formed above the second cavity.

### Example Embodiment 15

A method includes forming a substrate, placing a die on the substrate, placing an integrated heat spreader on the substrate and enclosing the die, the integrated heat spreader including a hole that extends through the integrated heat spreader, forming an air permeable adhesive to contact the integrated heat spreader and forming a cavity underneath the integrated heat spreader, and filling the cavity with a liquid metal thermal interface material. The hole that extends through the integrated heat spreader is plugged with sealant.

### Example Embodiment 16

The method of example embodiment 15, wherein the air permeable adhesive is formed on a perimeter of the substrate.

### Example Embodiment 17

The method of example embodiment 15, wherein the air permeable adhesive is formed on a perimeter of the die.

### Example Embodiment 18

The method of example embodiment 15, wherein the air permeable adhesive is formed outside of perimeter of the die and inside of a perimeter of the integrated heat spreader.

### Example Embodiment 19

The method of example embodiment 17, wherein a material having greater conductivity than the air permeable adhesive is formed above the air permeable adhesive.

### Example Embodiment 20

The method of example embodiment 19, wherein the material having greater conductivity than the air permeable adhesive determines the gap height between the integrated heat spreader and the die.

What is claimed is:

1. A package, comprising:
a substrate;
a die on the substrate;
an integrated heat spreader on the substrate that encloses the die, the integrated heat spreader including a hole that extends through the integrated heat spreader;
an air permeable adhesive contacting the integrated heat spreader and forming a cavity underneath the integrated heat spreader;
a liquid metal thermal interface material filling the cavity; and
a sealant plugging the hole that extends through the integrated heat spreader.

2. The package of claim 1, wherein the air permeable adhesive is formed on a perimeter of the substrate.

3. The package of claim 1, wherein the air permeable adhesive is formed on a perimeter of the die.

4. The package of claim 1, wherein the air permeable adhesive is formed outside of a perimeter of the die and inside of a perimeter of the integrated heat spreader.

5. The package of claim 3, wherein a material having greater conductivity than the air permeable adhesive is formed above the air permeable adhesive.

6. The package of claim 5, wherein the material having greater conductivity than the air permeable adhesive determines a gap height between the integrated heat spreader and the die.

7. The package of claim 6, wherein the hole is offset from the center of the die.

8. A package, comprising:
a substrate;
a first die on the substrate;
a second die on the substrate;
an integrated heat spreader on the substrate and enclosing the first die and the second die, the integrated heat spreader including a first hole and a second hole that extend through the integrated heat spreader;
a first air permeable adhesive contacting the integrated heat spreader and forming a first cavity underneath the integrated heat spreader and above the first die;
a second air permeable adhesive contacting the integrated heat spreader and forming a second cavity underneath the integrated heat spreader and above the second die;
a first liquid metal thermal interface material filling the first cavity;
a second liquid metal thermal interface material filling the second cavity;
a first sealant plugging the first hole that extends through the integrated heat spreader; and
a second sealant plugging the second hole that extends through the integrated heat spreader.

9. The package of claim 8, wherein the first die and the second die have different heights.

10. The package of claim 8, wherein a third air permeable adhesive is formed on a perimeter of the substrate.

11. The package of claim 8, wherein the first air permeable adhesive is formed on a perimeter of the first die.

12. The package of claim 8, wherein the second air permeable adhesive is formed on a perimeter of the second die.

13. The package of claim 8, wherein the first hole is formed above the first cavity.

14. The package of claim 8, wherein the second hole is formed above the second cavity.

15. A method, comprising:
forming a substrate;
placing a die on the substrate;
placing an integrated heat spreader on the substrate and enclosing the die, the integrated heat spreader including a hole that extends through the integrated heat spreader;
forming an air permeable adhesive to contact the integrated heat spreader and forming a cavity underneath the integrated heat spreader;
filling the cavity with a liquid metal thermal interface material; and
plugging the hole that extends through the integrated heat spreader with sealant.

16. The method of claim 15, wherein the air permeable adhesive is formed on a perimeter of the substrate.

17. The method of claim 15, wherein the air permeable adhesive is formed on a perimeter of the die.

18. The method of claim 15, wherein the air permeable adhesive is formed outside of a perimeter of the die and inside of a perimeter of the integrated heat spreader.

19. The method of claim 17, wherein a material having greater conductivity than the air permeable adhesive is formed above the air permeable adhesive.

20. The method of claim 19, wherein the material having greater conductivity than the air permeable adhesive determines the gap height between the integrated heat spreader and the die.
